(19) United States
(12) Patent Application Publication
(10) Pub. No.: US 2005/0034673 A1
(43) Pub. Date: Feb. 17, 2005

(54) Apparatus having edge frame and method of using the same

(76) Inventor: Jae-Gwan Kim, Gyeonggi-do (KR)

Correspondence Address: MARGER JOHNSON & MCCOLLOM PC, 1030 SW MORRISON STREET, PORTLAND, OR, 97205, US

(21) Appl. No.: 10/916,959

(22) Filed: Aug. 11, 2004

(30) Foreign Application Priority Data
Aug. 11, 2003 (KR) 2003-55530

(51) Int. Cl. C23C 16/00

(52) U.S. Cl. 118/728

(57) ABSTRACT

An apparatus for a semiconductor device includes: a chamber having upper and lower portions, a volume of the lower portion being greater than a volume of the upper portion; a susceptor in the chamber, the susceptor having a substrate on a top surface thereof; an injector injecting process gases into the chamber; a coil unit over the chamber; a radio frequency power supply connected to the coil unit; and an exhaust through the chamber.

The present invention claims the benefit of Korean Patent Application No. 2003-55530 filed on Aug. 11, 2003, which is hereby incorporated by reference.

### BACKGROUND OF THE INVENTION

1. Field of the Invention

The present invention relates to an apparatus for a semiconductor device, and more particularly, to an apparatus having an edge frame for a liquid crystal display device and a method of using the same.

2. Discussion of the Related Art

Liquid crystal display (LCD) devices are non-emissive devices that display images using a liquid crystal layer interposed between an array substrate and a color filter substrate. The array substrate and the color filter substrate may be fabricated by repetition of depositing a thin film on a transparent substrate such as a glass and patterning the deposited thin film. Recently, a plasma enhanced chemical vapor deposition (PECVD) method, where source gases are excited to a plasma state by an energy of high voltage and are deposited onto a substrate through a chemical reaction, has been widely used as a deposition technology of a thin film. An apparatus for an LCD device using a PECVD method will be illustrated hereinafter.

FIG. 1 is a schematic cross-sectional view showing an apparatus for a liquid crystal display device according to the related art. In FIG. 1, an inner space of a chamber 100 is isolated from an outer space by a chamber body 30. A susceptor 40 that a substrate 10 is loaded on is disposed in the chamber 100 and a heater (not shown) may be formed in the susceptor 40 to heat the substrate 10 when source gases are injected onto the substrate 10. Specifically, when the source gases are activated by a PECVD method, the susceptor 40 may function as a lower electrode. A susceptor supporter 46 extends from a central bottom portion of the susceptor 40 and a driving assembly 44 is combined with a lower circumference of the susceptor supporter 46. Since the driving assembly 44 is connected to a driving means 50 such as a motor, the susceptor 40 may move up and down according to steps of a fabrication process.

In addition, the chamber 100 includes an exhaust 38 connected to a vacuum pump (not shown). The chamber 100 may be evacuated to a high vacuum state by exhausting the inner space of the chamber 100 through the exhaust 38 during a fabrication process.

After the substrate 10 is loaded on the susceptor 40, the susceptor 40 moves up to a reaction region of the inner space of the chamber 100 and an edge frame 20 contacts a boundary portion of the substrate 10.

FIG. 2A is a schematic exploded perspective view showing an edge frame of an apparatus for a liquid crystal display device according to the related art and FIG. 2B is a schematic cross-sectional view showing an edge frame of an apparatus for a liquid crystal display device according to the related art. In FIGS. 2A and 2B, a susceptor 40 in a chamber 100 (of FIG. 1) of an apparatus includes a plurality of lift pin holes 48 and a plurality of lift pins 32 is disposed to correspond to the plurality of lift pin holes 48. Each lift pin 32 moves up and down through the corresponding lift pin hole 48 to support a substrate 10 during a loading and unloading steps. An edge frame 20 covers a substrate boundary portion 12 and an exposed susceptor boundary portion 42. Specifically, a substrate-covering portion 22 of the edge frame 20 contacts the substrate boundary portion 12 to prevent a leakage of source gases through a gap between the edge frame 20 and the substrate 10. Accordingly, the substrate-covering portion 22 is formed to be thinner than the other portion of the edge frame 20.

After the substrate 10 is loaded on the susceptor 40, the edge frame 20 contacts the substrate 10 and the susceptor 40 to cover the substrate boundary portion 12 and the susceptor boundary 42 by moving up the susceptor 40. At the same time, the edge frame 20 is detached from a frame supporter 34 formed on an inner wall of a chamber body 30.

FIGS. 3A and 3B are schematic cross-sectional views showing an operation of an edge frame of an apparatus for a liquid crystal display device according to the related art. In FIG. 3A, a substrate 10 is loaded on a susceptor 40. An edge frame 20 is supported by a frame supporter 34 such that an outer bottom surface 24 of the edge frame 20 contacts a top surface of the frame supporter 34. The edge frame 20 covers the substrate boundary portion 12 and the susceptor boundary portion 42 and is spaced apart from the substrate 10 and the susceptor 40. After loading the substrate 10 on the susceptor 40, the susceptor 40 moves up to a reaction region of a chamber 100 (of FIG. 1).

In FIG. 3B, as the susceptor 40 and the substrate 10 loaded on the susceptor 40 move up by the operation of a driving means 50 (of FIG. 1) connected to the driving assembly 46 (of FIG. 1), the edge frame 20 approaches the substrate 10 and the susceptor 40. Accordingly, the substrate-covering portion 22 contacts the substrate boundary portion 12 and a central portion of the edge frame 20 contacts the susceptor boundary portion 42. In addition, as the susceptor 40 further moves up, the outer bottom portion 24 of the edge frame 20 is detached from the top surface of the frame supporter 34. Then, the edge frame 20 moves up with the susceptor 40. Since the substrate-covering portion 22 contacts the substrate boundary portion 12, a leakage of source gases or plasma is prevented during a deposition process or an etch process.

However, since the edge frame 20 is formed of ceramic as a single body, the weight of the edge frame 20 is heavy and the pressure of the edge frame 20 to the substrate boundary portion 12 is high. The heavy weight and the high pressure may cause several problems in the fabrication process.

FIGS. 4A and 4B are schematic cross-sectional views showing problems caused by an edge frame of an apparatus for an LCD device according to the related art. As shown in FIG. 4A, a substrate boundary portion 12 of a substrate 10 may be broken due to the heavy weight and a high pressure of an edge frame 20. Accordingly, process yield is reduced.

In FIG. 4B, the edge frame 20 may have a thermal damage at a central portion thereof and may be warped due to a heat from a heater in a susceptor 40 or a heat from a fabrication process. Accordingly, a substrate-covering portion 22 does not contact the substrate boundary portion 12 and the central portion of the edge frame 20 is spaced apart from the susceptor 40 so that a gap between the edge frame 20 and the substrate 10 can be generated. As a result, source gases or plasma may be leaked through the gap between the edge frame 20 and the substrate 10 and may be deposited on the substrate boundary portion 12 and the susceptor boundary portion 42 (of FIGS. 3A and 3B). The leakage of the source gases or plasma may deteriorate uniformity of the fabrication process and may require more frequent chamber cleaning. In addition, the source gases or plasma may be consumed uneconomically.

### SUMMARY OF THE INVENTION

Accordingly, the present invention is directed to an apparatus for a semiconductor device that substantially obviates one or more of the problems due to limitations and disadvantages of the related art.

An object of the present invention is to provide an apparatus having an edge frame that prevents break of a substrate.

Another object of the present invention is to provide an apparatus having an edge frame that prevents leakage of source gases.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for a semiconductor device includes: a chamber; a susceptor in the chamber, wherein a substrate loaded on the susceptor has a substrate boundary portion and the susceptor has a susceptor boundary portion exposed outside the substrate boundary portion; an edge frame over the susceptor and the substrate, the edge frame comprising; a first sub-frame covering the substrate boundary portion and the susceptor boundary portion; and a second sub-frame surrounding the first sub-frame; and a frame supporter on a side wall of the chamber, the frame supporter supporting the second sub-frame.

In another aspect, an operation method of an apparatus for a semiconductor device includes; providing an edge frame in a chamber of the apparatus, the edge frame including a first sub-frame and a second sub-frame, the first sub-frame being supported by the second frame and the second sub-frame being supported by a frame supporter on a side wall of the chamber; loading a substrate on a susceptor in the chamber; moving up the susceptor having the substrate thereon, thereby the first and second sub-frames being supported by the susceptor; and moving up the susceptor having the substrate and the first and second sub-frames thereon, thereby the second sub-frame being detached from the frame supporter.

In another aspect, an operation method of an apparatus for a semiconductor device includes; providing an edge frame in a chamber of the apparatus, the edge frame including a first sub-frame and a second sub-frame, the first sub-frame being supported by the second frame and the second sub-frame being supported by a frame supporter on a side wall of the chamber; loading a substrate on a susceptor in the chamber; moving up the susceptor having the substrate thereon, thereby the first sub-frame being supported by the susceptor; and moving up the susceptor having the substrate and the first sub-frame thereon, wherein the second sub-frame remaining on the frame supporter.

In another aspect, an edge frame for an apparatus having a chamber, a susceptor in the chamber and a substrate on the susceptor includes: a first sub-frame covering a boundary portion of the substrate and a boundary portion of the susceptor; and a second sub-frame surrounding the first sub-frame.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic cross-sectional view showing an apparatus for a liquid crystal display device according to the related art;

FIG. 2A is a schematic exploded perspective view showing an edge frame of an apparatus for a liquid crystal display device according to the related art;

FIG. 2B is a schematic cross-sectional view showing an edge frame of an apparatus for a liquid crystal display device according to the related art;

FIGS. 3A and 3B are schematic cross-sectional views showing an operation of an edge frame of an apparatus for a liquid crystal display device according to the related art;

FIGS. 4A and 4B are schematic cross-sectional views showing problems caused by an edge frame of an apparatus for an LCD device according to the related art;

FIG. 5 is a schematic cross-sectional view of an apparatus having an edge frame according to an embodiment of the present invention;

FIG. 6A is a schematic exploded perspective view showing an edge frame of an apparatus for a liquid crystal display device according to an embodiment of the present invention;

FIG. 6B is a schematic cross-sectional view showing an edge frame of an apparatus for a liquid crystal display device according to an embodiment of the present invention;

FIG. 7 is a schematic cross-sectional view showing an edge frame of an apparatus for a liquid crystal display device according to another embodiment of the present invention;

FIGS. 8A to 8C are schematic cross-sectional views showing an operation of an edge frame of an apparatus for a liquid crystal display device according to another embodiment of the present invention;

FIG. 9A is a schematic exploded perspective view showing an edge frame of an apparatus for a liquid crystal display device according to another embodiment of the present invention;

FIG. 9B is a schematic cross-sectional view showing an edge frame of an apparatus for a liquid crystal display device according to another embodiment of the present invention; and

FIGS. 10A to 10C are schematic cross-sectional views showing an operation of an edge frame of an apparatus for a liquid crystal display device according to another embodiment of the present invention.

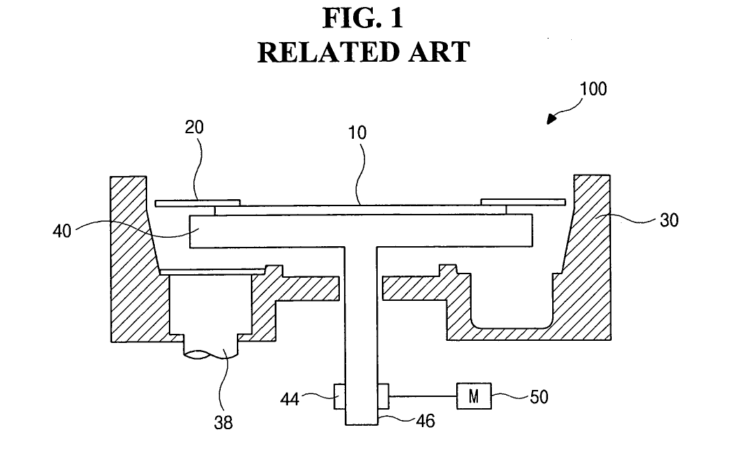

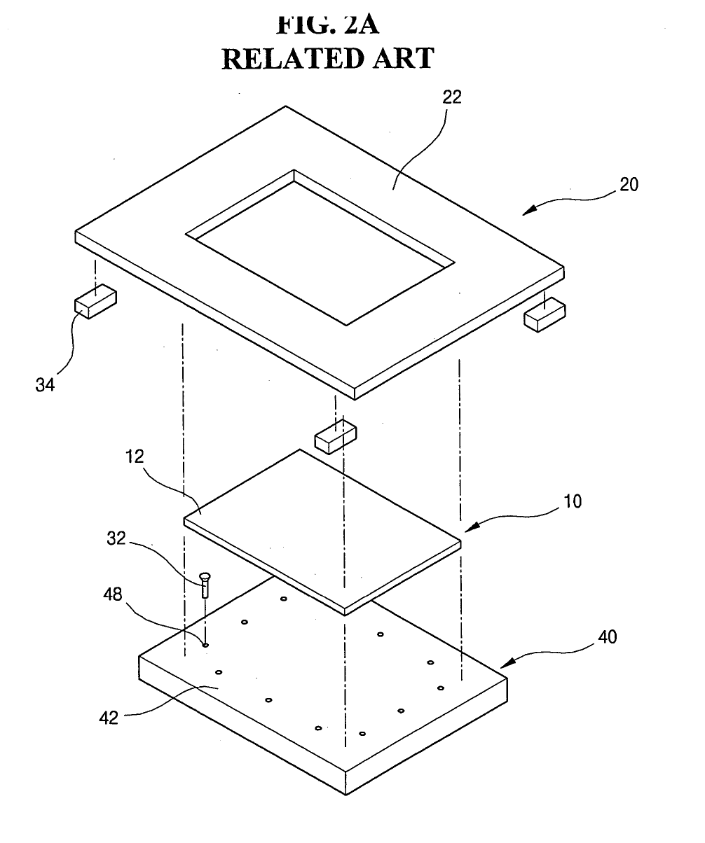

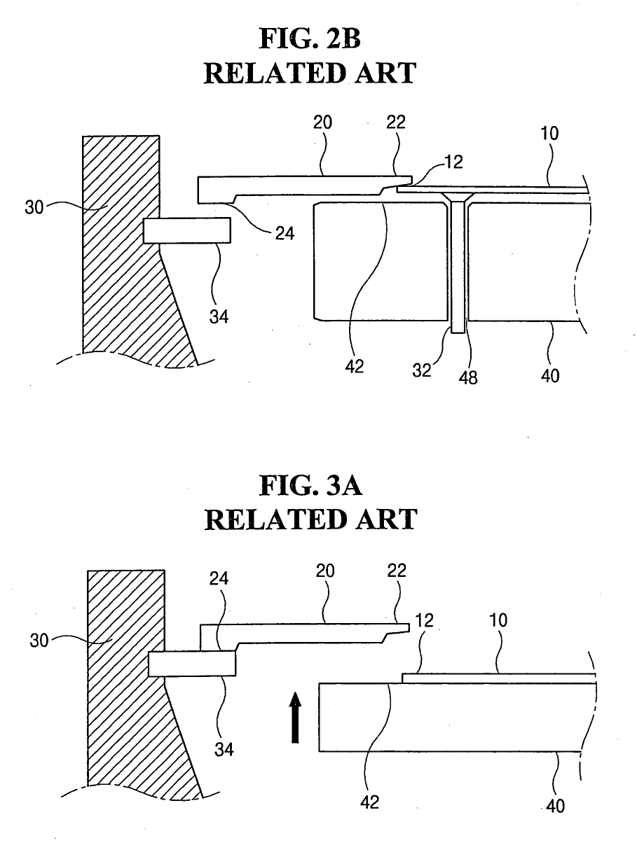

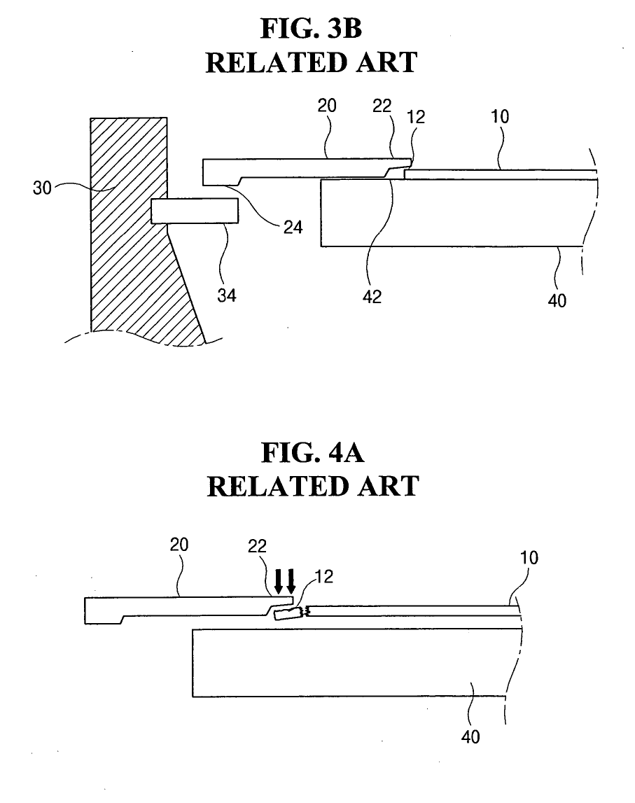

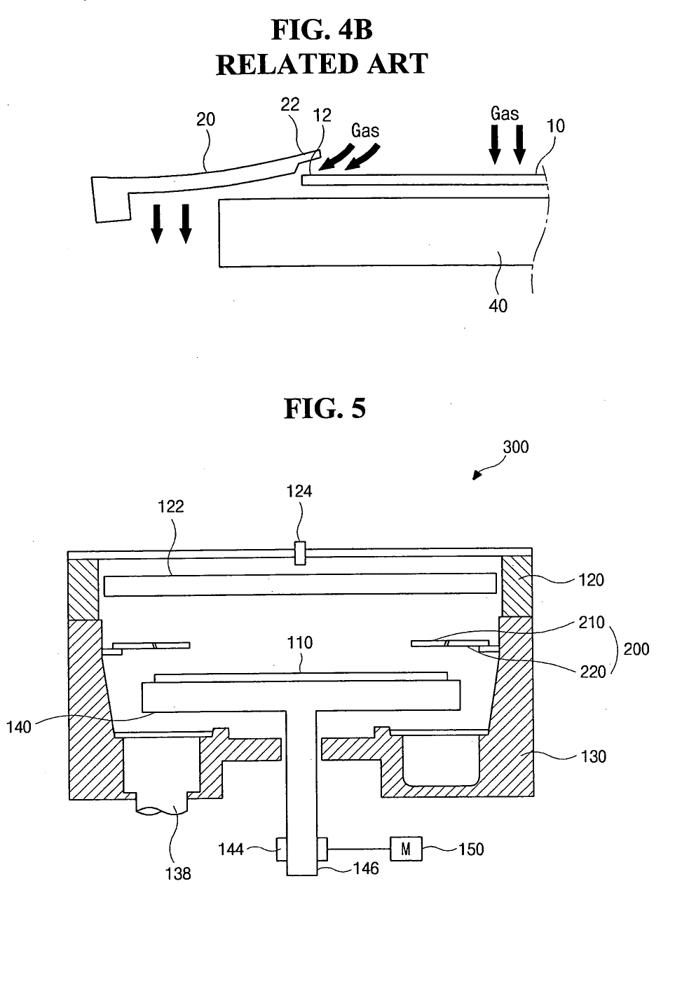

### DETAILED DESCRIPTION OF THE PREFERRED EMBODIMENTS

Reference will now be made in detail to the preferred embodiments, examples of which are illustrated in the accompanying drawings.

FIG. 5 is a schematic cross-sectional view of an apparatus having an edge frame according to an embodiment of the present invention.

In FIG. 5, a chamber 300 of an apparatus for a liquid crystal display (LCD) device includes a lead 120 and a chamber body 130. A gas-injecting unit 124 is formed through the lead 120 and connected to a gas-supplying unit (not shown). A shower head 122 is disposed in the lead 120 and source gases from the gas-injecting unit 124 are sprayed onto a substrate 110 through the shower head 122. In a plasma enhanced chemical vapor deposition (PECVD) type apparatus, for example, the shower head 122 may be connected to a radio frequency (RF) power supply and may function as an upper electrode that activates the source gases for a plasma state during a fabrication process. A susceptor 140 is disposed in the chamber body 130 and the substrate 110 is loaded on the susceptor 140. Even though not shown in FIG. 5, a heater may be formed in the susceptor 140 to heat the substrate 110 during a fabrication process. In a PECVD type apparatus, for example, the susceptor 140 may be grounded and may function as a lower electrode.

In addition, a susceptor supporter 146 extends from a central bottom portion of the susceptor 140 and a driving assembly 144 is combined with a lower circumference of the susceptor supporter 146. Since the driving assembly 144 is connected to a driving means 150 such as a motor outside the chamber 300, the susceptor 140 may move up and down according to steps of a fabrication process. Moreover, an exhaust 138 connected to a vacuum pump (not shown) is formed through the chamber body 130. The chamber 300 may be evacuated to a high vacuum state by exhausting an inner space of the chamber 300 through the exhaust 138 during a fabrication process.

Specifically, an edge frame 200 covering a substrate boundary portion of the substrate 110 is disposed adjacent to an inner surface of the chamber body 130. The edge frame 200 includes a first sub-frame 210 and a second sub-frame 220 contacting and surrounding the first sub-frame 210.

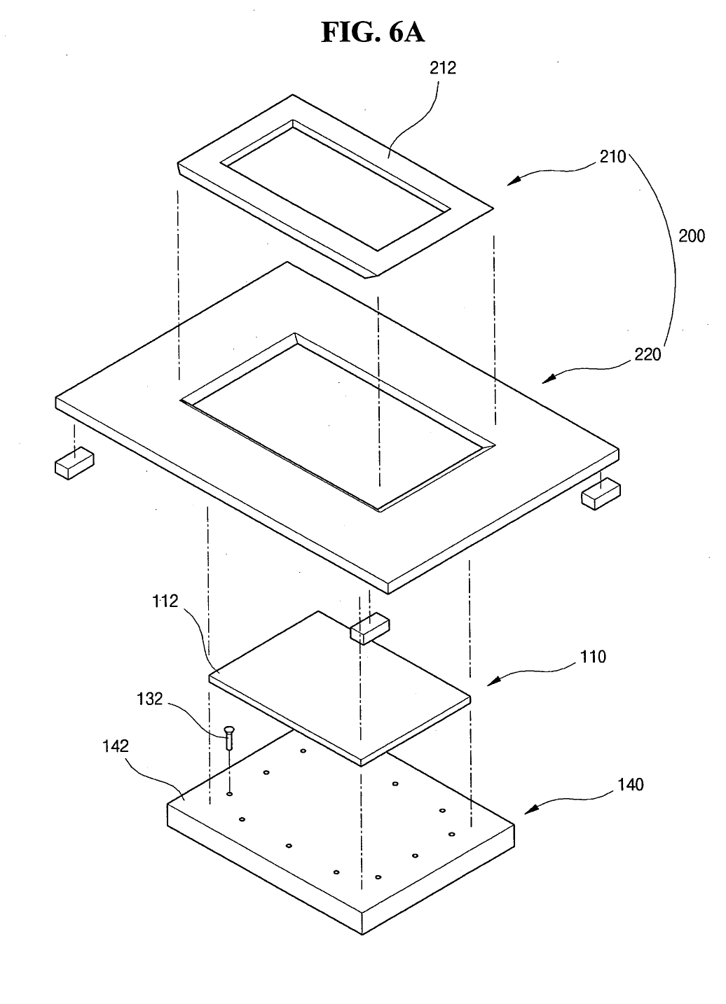

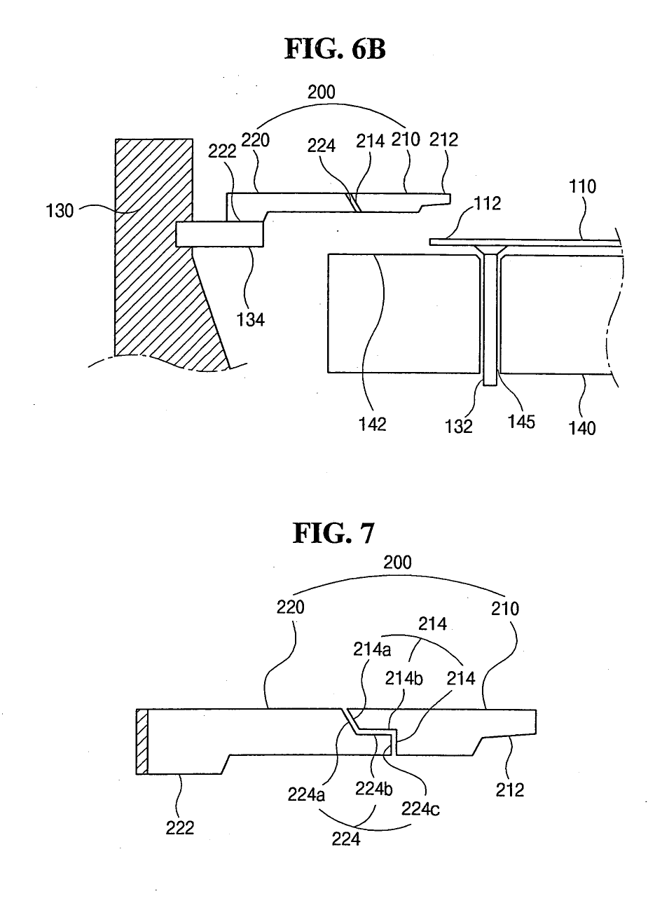

FIG. 6A is a schematic exploded perspective view showing an edge frame of an apparatus for a liquid crystal display device according to an embodiment of the present invention and FIG. 6B is a schematic cross-sectional view showing an edge frame of an apparatus for a liquid crystal display device according to an embodiment of the present invention.

In FIGS. 6A and 6B, a susceptor 140 in a chamber 300 (of FIG. 5) of an apparatus includes a plurality of lift pin holes 145 and a plurality of lift pins 132 is disposed to correspond to the plurality of lift pin holes 145. Each lift pin 132 moves up and down through the corresponding lift pin hole 145 to support a substrate 110 during a loading and unloading steps. As shown in FIGS. 6A, the plurality of lift pins 132 may be disposed to correspond to a substrate boundary portion 112. As a substrate is enlarged, the plurality of lift pins 132 may be disposed to correspond to a central portion of the substrate 110 in another embodiment. A diameter of a top portion of the lift pin 132 may be greater than a diameter of the lift pin hole 145 to prevent removal of the lift pin 132 from the lift pin hole 145. Accordingly, the top portion of the lift pin 132 may have a cone shape. Furthermore, a top portion of the lift pin hole 145 may have a shape corresponding to the top portion of the lift pin 132.

An edge frame 200 covering the substrate boundary portion 112 and a susceptor boundary portion 142 is disposed adjacent to an inner wall of a chamber body 130. The edge frame 200 includes a first sub-frame 210 and a second sub-frame 220 contacting and surrounding the first sub-frame 210. For example, a width of the first sub-frame 210 may be smaller than a width of the second sub-frame 220. The first sub-frame 210 covers the substrate boundary portion 112 and the susceptor boundary portion 142. Specifically, a substrate-covering portion 212 of the first sub-frame 210 may be formed to be thinner than the other portion of the edge frame 200. When the susceptor 140 moves up, the substrate-covering portion 212 contacts the substrate boundary portion 112, and the other portion of the first sub-frame 210 and the second sub-frame 220 contact the susceptor boundary portion 142. Accordingly, a leakage of source gases through a gap between the edge frame 200 and the substrate 110 is prevented.

In addition, a first contact portion 214 of the first sub-frame 210 and a second contact portion 224 of the second sub-frame 220 contacting each other may be inclined toward a center of the chamber 300 (of FIG. 5). That is, the first contact portion 214 and the second contact portion 224 may be inwardly inclined. A diameter of a top end of the first and second contact portions 214 and 224 is greater than a diameter of a bottom end of the first and second contact portions 214 and 224. Accordingly, the first sub-frame 210 can move up higher than the second sub-frame 220 and stop when the first sub-frame 210 has the same height as the second sub-frame 220. As a result, the first sub-frame 210 may be supported by the second sub-frame 220. For example, inclined surfaces of the first and second contact portions 214 and 224 may have an angle within a range of about 20° to about 70° with respect to a top surface of the substrate 110.

The second sub-frame 220 may be supported by a frame supporter 134 such that an outer bottom portion 222 contacts a top surface of the frame supporter 134. The outer bottom portion 222 may extend from the second sub-frame 220 downwardly. Even though the susceptor 140 and the edge frame 200 have a rectangular shape in plan view, the susceptor 140 and the edge frame 200 may have various shapes such as a circle in another embodiment.

A cross-sectional shape and a position of the contact portions between the first and second sub-frames 210 and 220 may vary as an embodiment.

FIG. 7 is a schematic cross-sectional view showing an edge frame of an apparatus for a liquid crystal display device according to another embodiment of the present invention.

In FIG. 7, an edge frame 200 includes a first sub-frame 210 and a second sub-frame 220 contacting and surrounding the first sub-frame 210. A substrate-covering portion 212 of the first sub-frame 210 is thinner than the other portion of the first sub-frame 210 to contact and press a substrate boundary portion 112 (of FIG. 6B) of a substrate 110 (of FIG. 6B). Moreover, an outer bottom portion 222 of the second sub-frame 220 extends from the second sub-frame 220 and contacts a susceptor supporter 134 (of FIG. 6B).

A first contact portion 214 of the first sub-frame 210 contacts a second contact portion 224 of the second sub-frame 220. The first contact portion 214 includes a first inclined surface 214a, a first horizontal surface 214b and a first vertical surface 214c, and the second contact portion includes a second inclined surface 224a, a second horizontal surface 224b and a second vertical surface 224c. The first and second inclined surfaces 214a and 224a are inclined to have an angle with respect to a horizontal direction. For example, the first and second inclined surfaces 214a and 224a may have an angle within a range of about 20° to about 70° with respect to a top surface of the substrate 110 (of FIG. 6B). The first and second horizontal surfaces 214b and 224b may be parallel to a horizontal line, and the first and second vertical surfaces 214c and 224c may be perpendicular to a horizontal line. Accordingly, the first horizontal surface 214b is substantially perpendicular to the first vertical surface 214c, and the second horizontal surface 224b is substantially perpendicular to the second vertical surface 224c. Moreover, as a whole, the first contact portion 214 is disposed over the second contact portion 224. Since the first and second horizontal surfaces 214b and 224b are flat, the first sub-frame 210 is supported by the second sub-frame 220 more stably.

As compared with an edge frame of FIG. 6B, a lower portion of the first contact portion 214 of the first sub-frame 210 sinks toward a center of the chamber 300 (of FIG. 5) and a lower portion of the second contact portion 224 of the second sub-frame 220 protrudes toward a center of the chamber 300 (of FIG. 5). As a result, the first sub-frame 210 has a “T” shape in cross-sectional view such that two upper end portions are protruded outwardly.

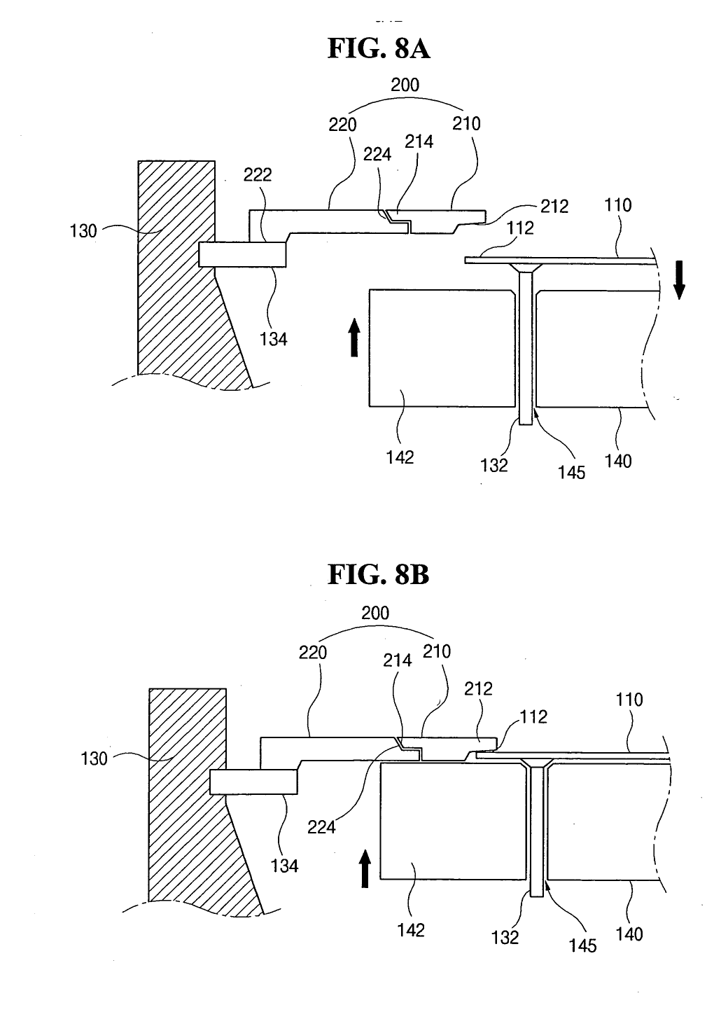

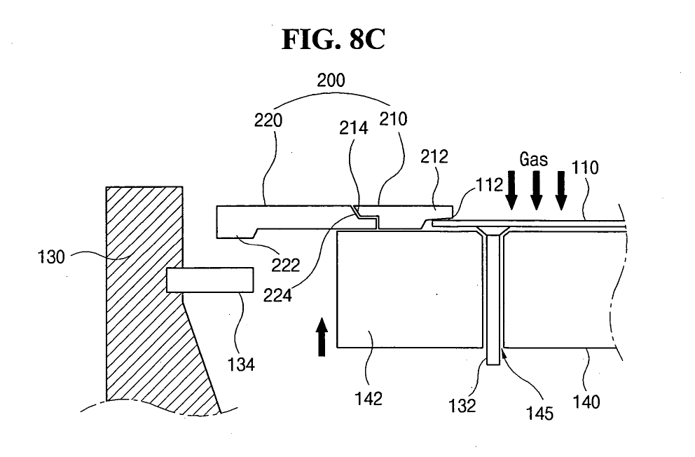

FIGS. 8A to 8C are schematic cross-sectional views showing an operation of an edge frame of an apparatus for a liquid crystal display device according to another embodiment of the present invention.

In FIG. 8A, a substrate 110 is loaded into a chamber 300 (of FIG. 5) and supported by a plurality of lift pins 132 through a plurality of lift pin holes 145 of a susceptor 140. A frame supporter 134 is formed on an inner wall of a chamber body 130. An edge frame 200 covers a substrate boundary portion 112 and a susceptor boundary portion 142. The edge frame 200 includes a first sub-frame 210 and a second sub-frame 220 contacting and surrounding the first sub-frame 210. Since a first contact portion 214 of the first sub-frame 210 is disposed over a second contact portion 224 of the second sub-frame 220, the first sub-frame is supported by the second sub-frame 220. The second sub-frame 220 is supported by a frame supporter 134 such that an outer bottom surface 222 of the second sub-frame 220 contacts a top surface of the frame supporter 134. The first sub-frame 210 covers the substrate boundary portion 112 and the susceptor boundary portion 142 and the second frame covers the susceptor boundary portion 142. Moreover, the first and second sub-frames 210 and 220 are spaced apart from the substrate 110 and the susceptor 140.

In FIG. 8B, as the susceptor 140 moves up by a driving means 150 (of FIG. 5), the plurality of lift pins 132 relatively move down through a plurality of lift pin holes 145. After the substrate 110 contacts the susceptor 140, the substrate 110 is supported by the susceptor 140 instead of the plurality of lift pins 132. The susceptor 140 having the substrate 110 thereon further moves up even after the substrate 110 contacts the susceptor 140. Accordingly, the substrate 110 and the susceptor 140 contact the edge frame 200 such that the first sub-frame covers the substrate boundary portion 112 and the susceptor boundary portion 142 and the second frame covers the susceptor boundary portion 142. Specifically, the first sub-frame 210 effectively covers the substrate boundary portion 112 because of a substrate-covering portion thinner than the other portion of the first sub-frame 210. After the edge frame 200 contacts the substrate 110 and the susceptor 140, the edge frame 200 is supported by the susceptor 140 having the substrate 110 thereon instead of the frame supporter 134.

In FIG. 8C, the susceptor 140 having the substrate 110 and the edge frame 200 thereon further moves up to a reaction region of the chamber 300 (of FIG. 5) even after the edge frame 200 contacts the substrate 110 and the susceptor 140. Accordingly, the outer bottom surface 222 of the second sub-frame 220 is detached from the frame supporter 134. In the reaction region, the source gases may be deposited onto the substrate 110.

The edge frame 200 is divided into the first sub-frame 210 and the second sub-frame 220 such that a width of the first sub-frame 210 is smaller than a width of the second sub-frame 220. Accordingly, the first sub-frame 210 covering the substrate boundary portion 112 is lighter than the second sub-frame 220. Since only the first sub-frame 210 having a lighter weight contacts and presses the substrate 110, a break of the substrate 110 due to a weight of the edge frame 200 is prevented.

In addition, since the first sub-frame 210 is closer to a center of the susceptor 140 than the second sub-frame 220, a heat from a heater (not shown) in the susceptor 140 is transmitted to the first sub-frame 210 first. The heat transmitted to the first sub-frame 210 is not completely transmitted to the second sub-frame 220 and some of the heat disappears during the transmission. Since the first sub-frame 210 is formed to have a width smaller than that of the second sub-frame 220, the first sub-frame 210 is not warped due to the heat. Accordingly, the first sub-frame 210 completely contacts the substrate boundary portion 112 and the second sub-frame 220 completely contacts the susceptor boundary portion 142. As a result, a gap is not generated between the edge frame 200 and the substrate 110 and the source gases are not deposited on the susceptor boundary portion 142.

After finishing the fabrication process, the susceptor 140 having the substrate 110 and the edge frame 200 thereon moves down. When the second sub-frame 220 contacts the frame supporter 134, the edge frame 200 is supported by the frame supporter 134 and separated from the susceptor 140. After the edge frame 200 is separated, the susceptor 140 keeps moving down. The plurality of lift pins 132 relatively moves up after bottom ends of the lift pins 132 contacts a supporting means or a bottom of the chamber 300 (of FIG. 5). Accordingly, the substrate 110 is supported by the plurality of lift pins 132 and then unloaded by a robot arm.

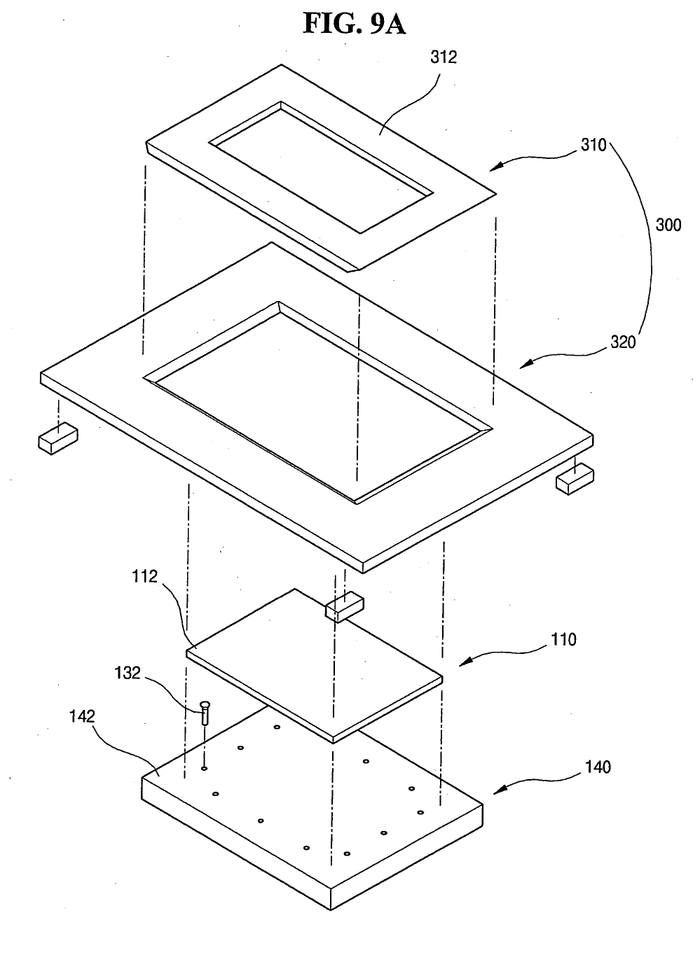

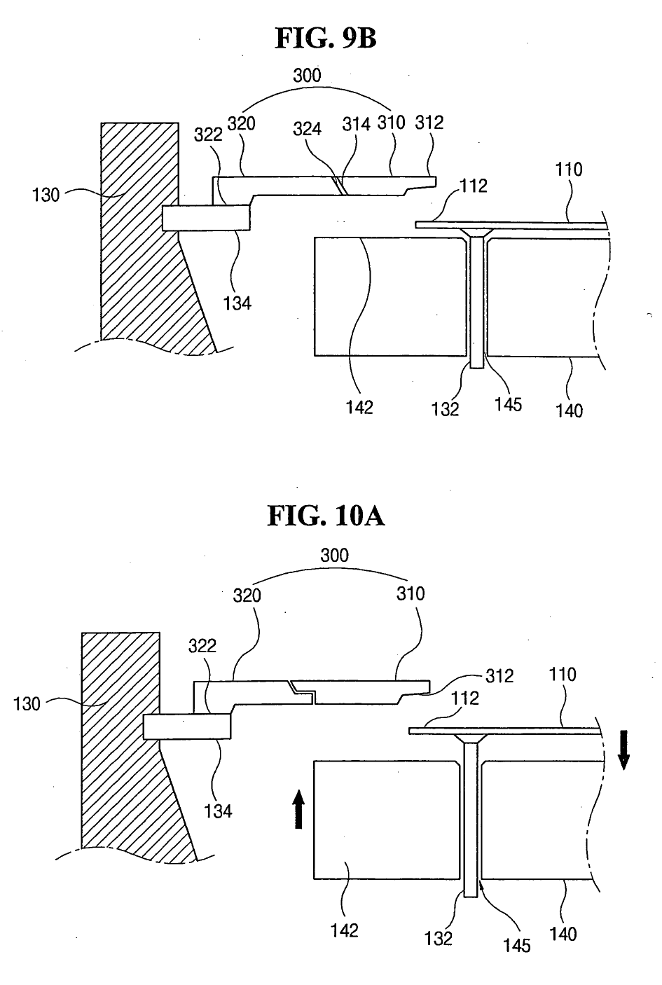

FIG. 9A is a schematic exploded perspective view showing an edge frame of an apparatus for a liquid crystal display device according to another embodiment of the present invention and FIG. 9B is a schematic cross-sectional view showing an edge frame of an apparatus for a liquid crystal display device according to another embodiment of the present invention.

In FIGS. 9A and 9B, a susceptor 140 in a chamber 300 (of FIG. 5) of an apparatus includes a plurality of lift pin holes 145 and a plurality of lift pins 132 is disposed to correspond to the plurality of lift pin holes 145. Each lift pin 132 moves up and down through the corresponding lift pin hole 145 to support a substrate 110 during a loading and unloading steps. As shown in FIGS. 9A, the plurality of lift pins 132 may be disposed to correspond to a substrate boundary portion 112. As a substrate is enlarged, the plurality of lift pins 132 may be disposed to correspond to a central portion of the substrate 110 in another embodiment. A diameter of a top portion of the lift pin 132 may be greater than a diameter of the lift pin hole 145 to prevent removal of the lift pin 132 from the lift pin hole 145. Accordingly, the top portion of the lift pin 132 may have a cone shape. Furthermore, a top portion of the lift pin hole 145 may have a shape corresponding to the top portion of the lift pin 132.

An edge frame 300 covering the substrate boundary portion 112 and a susceptor boundary portion 142 is disposed adjacent to an inner wall of a chamber body 130. The edge frame 300 includes a first sub-frame 310 and a second sub-frame 320 contacting and surrounding the first sub-frame 310. Differently from the edge frame 200 of FIGS. 6A and 6B, a width of the first sub-frame 310 may be equal to or larger than a width of the second sub-frame 320. Accordingly, the first sub-frame 310 covers the substrate boundary portion 112 and the susceptor boundary portion 142, and the second sub-frame 320 contacts the first sub-frame 310 outside the susceptor 140. The second sub-frame 320 does not cover the susceptor boundary portion 142.

A substrate-covering portion 312 of the first sub-frame 310 may be formed to be thinner than the other portion of the edge frame 300. When the susceptor 140 moves up, the substrate-covering portion 312 contacts the substrate boundary portion 112, and the other portion of the first sub-frame 310 contacts the susceptor boundary portion 142. Accordingly, a leakage of source gases through a gap between the edge frame 300 and the substrate 110 is prevented.

In addition, a first contact portion 314 of the first sub-frame 310 and a second contact portion 324 of the second sub-frame 320 contacting each other may be inclined toward a center of the chamber 300 (of FIG. 5). Accordingly, the first sub-frame 310 can move up higher than the second sub-frame 320 and stop when the first sub-frame 310 has the same height as the second sub-frame 320. As a result, the first sub-frame 310 may be supported by the second sub-frame 320. For example, inclined surfaces of the first and second contact portions 314 and 324 may have an angle within a range of about 20° to about 70° with respect to a top surface of the substrate 110.

The second sub-frame 320 may be supported by a frame supporter 134 such that an outer bottom portion 322 contacts a top surface of the frame supporter 134. The outer bottom portion 322 may extend from the second sub-frame 320 downwardly. Since the second sub-frame 320 does not move with the susceptor 140, the second sub-frame 320 may be fixed on the frame supporter 134. Even though the susceptor 140 and the edge frame 300 have a rectangular shape in plan view, the susceptor 140 and the edge frame 300 may have various shapes such as a circle in another embodiment. Moreover, a cross-sectional shape of the contact portions between the first and second sub-frames 310 and 320 may vary as an embodiment.

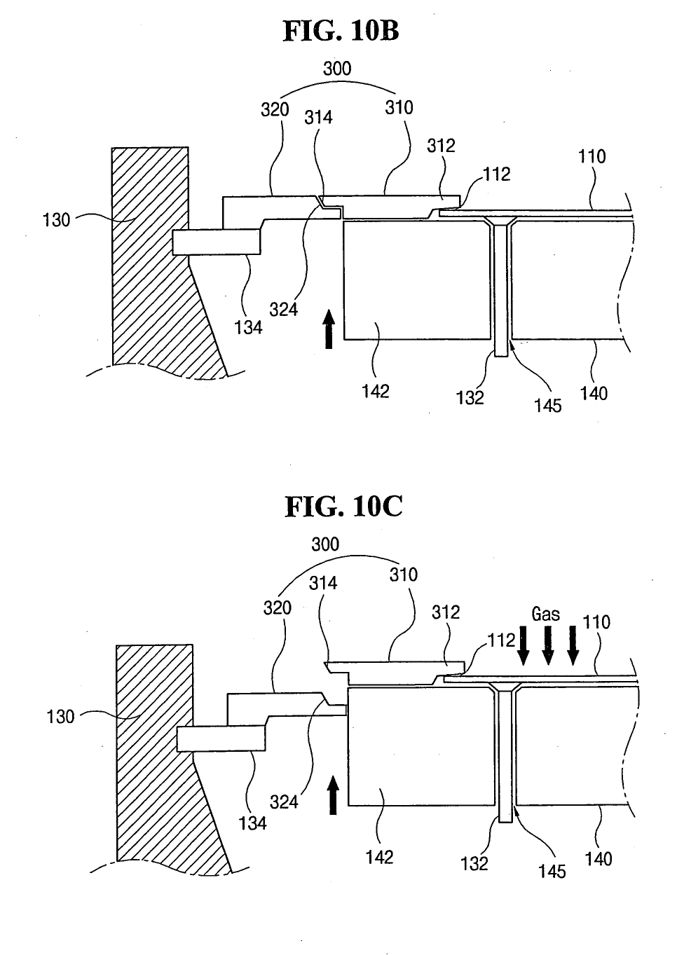

FIGS. 10A to 10C are schematic cross-sectional views showing an operation of an edge frame of an apparatus for a liquid crystal display device according to another embodiment of the present invention.

In FIG. 10A, a substrate 110 is loaded into a chamber 300 (of FIG. 5) and supported by a plurality of lift pins 132 through a plurality of lift pin holes 145 of a susceptor 140. A frame supporter 134 is formed on an inner wall of a chamber body 130. An edge frame 300 covers a substrate boundary portion 112 and a susceptor boundary portion 142. The edge frame 300 includes a first sub-frame 310 and a second sub-frame 320 contacting and surrounding the first sub-frame 310. Since a first contact portion 314 of the first sub-frame 310 is disposed over a second contact portion 324 of the second sub-frame 320, the first sub-frame 310 can be supported by the second sub-frame 320. The second sub-frame 320 is supported by a frame supporter 134 such that an outer bottom surface 322 of the second sub-frame 320 contacts a top surface of the frame supporter 134. The first sub-frame 310 covers the substrate boundary portion 112 and the susceptor boundary portion 142, while the second frame does not cover the susceptor boundary portion 142. Moreover, the first and second sub-frames 310 and 320 are spaced apart from the substrate 110 and the susceptor 140.

In FIG. 10B, as the susceptor 140 moves up by a driving means 150 (of FIG. 5), the plurality of lift pins 132 relatively move down through a plurality of lift pin holes 145. After the substrate 110 contacts the susceptor 140, the substrate 110 is supported by the susceptor 140 instead of the plurality of lift pins 132. The susceptor 140 having the substrate 110 thereon further moves up even after the substrate 110 contacts the susceptor 140. Accordingly, the substrate 110 and the susceptor 140 contact the edge frame 300 such that the first sub-frame 310 covers the substrate boundary portion 112 and the susceptor boundary portion 142. However, since the second sub-frame 320 does not cover the susceptor boundary portion 142, the second sub-frame 320 does not contact the susceptor 140. The first sub-frame 310 effectively covers the substrate boundary portion 112 because of a substrate-covering portion 312 thinner than the other portion of the first sub-frame 310. In addition, the first contact portion 314 contacts the second contact portion 324 such that the first contact portion 314 is disposed over the second contact portion 324. After the first sub-frame 310 contacts the substrate 110 and the susceptor 140, the first sub-frame 310 is supported by the susceptor 140 having the substrate 110 thereon.

In FIG. 10C, the susceptor 140 having the substrate 110 and the first sub-frame 310 thereon further moves up to a reaction region of the chamber 300 (of FIG. 5) even after the first sub-frame 310 contacts the substrate 110 and the susceptor 140. However, the second sub-frame 320 is not supported by the susceptor 140, the second sub-frame 320 does not move up and is not detached from the frame supporter 134. Accordingly, the first sub-frame 310 is detached from the second sub-frame 320. Since the second sub-frame 320 is not detached from the frame supporter 134, the second sub-frame 320 may be fixed on the frame supporter 134. In the reaction region, the source gases may be deposited onto the substrate 110.

In this embodiment, the edge frame 300 is divided into the first sub-frame 310 and the second sub-frame 320 such that a width of the first sub-frame 310 is equal to or larger than a width of the second sub-frame 320. Accordingly, only the first sub-frame 310 moves up with the susceptor 140 to the reaction region and the second sub-frame remains on the frame supporter 134 in a region under the reaction region. As a result, only the first sub-frame 310 presses the substrate boundary portion 112 and the susceptor boundary portion 142 during a fabrication process. Specifically, the substrate boundary portion 112 is covered with the substrate-covering portion 312 thinner than the other portion of the first sub-frame 310. Since the whole edge frame 300 does not press the substrate 110, a break of the substrate 110 due to a weight of the edge frame 300 is prevented.

In addition, since the first sub-frame 310 is disposed on the susceptor 140 and the second sub-frame 320 is separated from the first sub-frame 310, a heat from a heater (not shown) in the susceptor 140 is transmitted only to the first sub-frame 310 and the heat transmitted to the first sub-frame 310 is not transmitted to the second sub-frame 320. Accordingly, the edge frame 300 is not warped due to the heat and the first sub-frame 310 completely contacts the substrate boundary portion 112 and the susceptor boundary portion 142. As a result, a gap is not generated between the edge frame 300 and the substrate 110, and a deposition of the source gases on the susceptor boundary portion 142 is prevented.

After finishing the fabrication process, the susceptor 140 having the substrate 110 and the first sub-frame 310 thereon moves down. When the first sub-frame 310 contacts the second sub-frame 320, the edge frame 300 is supported by the frame supporter 134 and separated from the susceptor 140. Even after the edge frame 300 is separated, the susceptor 140 keeps moving down. The plurality of lift pins 132 relatively moves up after bottom ends of the lift pins 132 contacts a supporting means or a bottom of the chamber 300 (of FIG. 5). Accordingly, the substrate 110 is supported by the plurality of lift pins 132 and then unloaded by a robot arm.

In an embodiment of the present invention, a weight of a portion substantially covering and pressing the substrate is reduced by using an edge frame divided into independent portions. Accordingly, a break of the substrate due to the edge frame is prevented and a production yield is improved. Furthermore, since a heat from the susceptor is transmitted to the portion substantially covering and pressing the substrate, a warpage of the whole edge frame due to a thermal stress is prevented. As a result, a leakage of source gases onto the susceptor is prevented and efficiency of an apparatus is improved due to extension of cleaning time period.

It will be apparent to those skilled in the art that various modifications and variations can be made in the apparatus having an edge frame without departing from the spirit or scope of the invention. Thus, it is intended that the present invention covers the modifications and variations of this invention provided they come within the scope of the appended claims and their equivalents.

1. An apparatus for a semiconductor device, comprising:
a chamber;
a susceptor in the chamber, wherein a substrate loaded on the susceptor has a substrate boundary portion and the susceptor has a susceptor boundary portion exposed outside the substrate boundary portion;
an edge frame over the susceptor and the substrate, the edge frame comprising;
a first sub-frame covering the substrate boundary portion and the susceptor boundary portion; and
a second sub-frame surrounding the first sub-frame; and
a frame supporter on a side wall of the chamber, the frame supporter supporting the second sub-frame.

2. The apparatus according to claim 1, wherein a first contact surface of the first sub-frame contacts a second contact surface of the second sub-frame, and the first and second contact surfaces are inwardly inclined.

3. The apparatus according to claim 1, wherein the first sub-frame has a substrate-covering portion corresponding to the substrate boundary portion and the substrate-covering portion is substantially thinner than the other portion of the first sub-frame.

4. The apparatus according to claim 1, wherein the first sub-frame has a first inclined surface, a first horizontal surface and a first vertical surface and the second sub-frame has a second inclined surface, a second horizontal surface and a second vertical surface, wherein the first inclined surface, the first horizontal surface and the first vertical surface contact the second inclined surface, the second horizontal surface and the second vertical surface, respectively.

5. The apparatus according to claim 4, wherein the first and second inclined surfaces are inwardly inclined.

6. The apparatus according to claim 4, wherein the first horizontal surface is disposed over the second horizontal surface.

7. The apparatus according to claim 1, wherein a width of the first sub-frame is smaller than a width of the second sub-frame.

8. The apparatus according to claim 7, wherein the second sub-frame covers the susceptor boundary portion.

9. The apparatus according to claim 1, wherein a width of the first sub-frame is equal to or greater than a width of the second sub-frame.

10. The apparatus according to claim 9, wherein the second sub-frame is disposed outside the susceptor.

11. The apparatus according to claim 1, further comprising;
a gas-injecting unit injecting source gases into the chamber;
a shower head spraying the source gases onto the substrate;
a plurality of lift pins through a plurality of lift pin holes of the susceptor; and
an exhaust exhausting the source gases from the chamber.

12. An operation method of an apparatus for a semiconductor device, comprising;
providing an edge frame in a chamber of the apparatus, the edge frame including a first sub-frame and a second sub-frame, the first sub-frame being supported by the second frame and the second sub-frame being supported by a frame supporter on a side wall of the chamber;
loading a substrate on a susceptor in the chamber;
moving up the susceptor having the substrate thereon, thereby the first and second sub-frames being supported by the susceptor; and
moving up the susceptor having the substrate and the first and second sub-frames thereon, thereby the second sub-frame being detached from the frame supporter.

13. The method according to claim 12, further comprising;
spraying source gases onto the substrate;
moving down the susceptor having the substrate and the first and second sub-frames thereon, thereby the second sub-frame being supported by the frame supporter;
moving down the susceptor having the substrate thereon, thereby the first and second sub-frames being detached from the susceptor; and
unloading the substrate from the chamber.

14. An operation method of an apparatus for a semiconductor device, comprising;
providing an edge frame in a chamber of the apparatus, the edge frame including a first sub-frame and a second sub-frame, the first sub-frame being supported by the second frame and the second sub-frame being supported by a frame supporter on a side wall of the chamber;
loading a substrate on a susceptor in the chamber;
moving up the susceptor having the substrate thereon, thereby the first sub-frame being supported by the susceptor; and
moving up the susceptor having the substrate and the first sub-frame thereon, wherein the second sub-frame remaining on the frame supporter.

15. The method according to claim 14, further comprising;
spraying source gases onto the substrate;
moving down the susceptor having the substrate and the first sub-frame thereon, thereby the first sub-frame being supported by the second sub-frame;
moving down the susceptor having the substrate thereon, thereby the first sub-frame being detached from the susceptor; and
unloading the substrate from the chamber.

16. An edge frame for an apparatus having a chamber, a susceptor in the chamber and a substrate on the susceptor, comprising:
a first sub-frame covering a boundary portion of the substrate and a boundary portion of the susceptor; and
a second sub-frame surrounding the first sub-frame.

17. The edge frame according to claim 16, wherein a first contact portion of the first sub-frame is disposed over a second contact surface of the second sub-frame.

18. The edge frame according to claim 16, wherein the first sub-frame has a first inclined surface, a first horizontal surface and a first vertical surface and the second sub-frame has a second inclined surface, a second horizontal surface and a second vertical surface, wherein the first inclined surface, the first horizontal surface and the first vertical surface contact the second inclined surface, the second horizontal surface and the second vertical surface, respectively.

19. The edge frame according to claim 16, wherein the second sub-frame covers the boundary portion of the susceptor.

20. The edge frame according to claim 16, wherein the second sub-frame is disposed outside the susceptor.
